(19) United States
(12) Patent Application Publication
(10) Pub. No.: US 2019/0049531 A1
(43) Pub. Date: Feb. 14, 2019

(54) CALCULATING METHOD FOR ULTIMATE DEMAGNETIZATION TEMPERATURE OF LOUDSPEAKER MAGNETIC STEEL

(71) Applicant: Premium Loudspeakers (Hui Zhou) Co., Ltd., Huizhou City (CN)

(72) Inventor: Zhiwen CHEN, Huizhou City (CN)

(21) Appl. No.: 16/100,838

(22) Filed: Aug. 10, 2018

(30) Foreign Application Priority Data
Aug. 10, 2017 (CN) 201710681056.1

(51) Int. Cl. G01R 33/14; H04R 31/00; H04R 29/00; H01F 13/00; G01R 33/00; G06F 17/11

(52) U.S. Cl. CPC G01R 33/14; H04R 31/00; H04R 29/001; G06F 17/11; G01R 33/0064; G01R 33/007; H01F 13/006

(57) ABSTRACT

A calculating method for ultimate demagnetization temperature of loudspeaker magnetic steel includes drawing a 2D or 3D geometric model view of the system; importing the performance parameter of magnetic steel and designing variables to be solved and formulas; establishing a finite element model for the system according to the imported performance parameter of magnetic steel, variables and formulas; solving and conducting a steady-state analysis of the finite element model for a coordinate (Hn, Bn), a loadline slope Pc value and an ultimate demagnetization temperature value of the operation point under 20° C. on BH curve by calculating; obtaining a demagnetization curve view with post-treatment. Thus, a value of loadline slope Pc is obtained, and the ultimate demagnetization temperature of loudspeaker magnetic steel can be obtained importing the variables and formulas into FEA simulation through the temperature coefficient of magnetic steel and by the solution and steady-state analysis using COMSOL Multiphysics software.

### CROSS REFERENCE TO RELATED APPLICATIONS

This application claims priority to CN 201710681056.1, which was filed on Aug. 10, 2017, and which is herein incorporated by reference.

### TECHNICAL FIELD

The present invention relates to the technical field of performance tests for loudspeaker magnetic steel, in particular, to a calculating method for ultimate demagnetization temperature of loudspeaker magnetic steel.

### BACKGROUND

The magnetic steel of loudspeakers or the magnetic field of magnets is influenced greatly by temperature. The magnetic field intensity of NdFeB magnets may slow down with a rise in temperature, and the process is reversible. When the temperature reaches a certain ultimate demagnetization temperature, magnetic field intensity of NdFeB magnets may show a sharp decline, and even if the temperature turns back to room temperature, the magnetic field intensity cannot return to the previous strength. Such process is irreversible. Similarly, the magnetic field intensity of ferrite magnets may slow down with a decrease in temperature and the process is reversible. That is, when the temperature reaches a certain ultimate demagnetization temperature, irreversible demagnetization may emerge. In order to compute the demagnetization temperature of a loudspeaker and estimate the overall performance thereof, traditional calculating methods for ultimate demagnetization temperature of loudspeaker magnetic steel may generally comprise the following three steps:

(1) Calculating the specific size of a loudspeaker magnetic loop system and using the formula

$$Pc = \frac{LmAg σ}{AmLgf}$$

for loadline slope to estimate a corresponding magnetic flux leakage coefficient σ and a magnetoresistive coefficient f for calculating loadline slope Pc, wherein Lm is the thickness of the magnet, Am is the superficial area of the magnet, Ag is the superficial area of the magnetic gap, Lg is the thickness of the magnetic gap, σ is the magnetic flux leakage coefficient and f is the magnetoresistive coefficient. The loadline is determined by the size of the magnetic system. The slope of the load line helps determine the operation point of the loudspeaker magnet and further find the demagnetization temperature for the loudspeaker.
(2) Utilizing a graphic method to depict a loadline on the demagnetization curve provided by a magnet steel supplier, where the intersection point of the loadline and the demagnetization curve is the operation point of the loudspeaker magnetic steel on this demagnetization curve under the corresponding temperature.
(3) It is necessary to find as many as possible demagnetization curves, in order to know the operating temperature of multiple temperatures, and when the operation point under a certain temperature overlaps with the knee point of the demagnetization curve, this temperature is the ultimate demagnetization temperature of magnetic steel.

However, the above formulas for calculating loadline slope Pc in the traditional calculating method for ultimate demagnetization temperature of loudspeaker magnetic steel is not applicable to the opposite magnetic loop systems (or abnormal shape of magnetic loop systems) and the magnetic loop system of multiple magnetic steels as such formulas introduce the magnetic flux leakage coefficient σ and magnetoresistive coefficient which are difficult to find out an accurate coefficient value, the computed Pc is led to be with errors. At the same time, since there are 3-5 demagnetization curves of different temperatures and the highest temperature therein is the operation temperature in magnetic steel performance table, the final calculation is also difficult.

Thus, based on the above factors, it is an urgent technical problem to be solved by those skilled in the art to quickly calculate the demagnetization temperature of loudspeaker magnetic steel.

### SUMMARY

To solve the above problems in the prior art, the present invention provides a calculating method for ultimate demagnetization temperature of loudspeaker magnetic steel based on finite-element analysis (FEA) simulation of magnetic loop system. Through such method, an operation point at room temperature (20° C.) can be obtained and a value of loadline slope Pc can be further precisely obtained, and the ultimate demagnetization temperature of loudspeaker magnetic steel in a loudspeaker magnetic circuit system can be obtained accurately in the end by importing the to-be-solved variables and formulas into a FEA simulation through the temperature coefficient of magnetic steel itself and, hence, by the solution and steady-state analysis using COMSOL Multiphysics software, which is a cross-platform finite-element analysis, solver and multiphysics simulation software.

To achieve the above purpose, the present invention further provides the following technical scheme:

A calculating method for ultimate demagnetization temperature of loudspeaker magnetic steel, comprising:

S1. Drawing a 2D or 3D geometric model view of the loudspeaker magnetic circuit system;

S2. Importing the performance parameter of magnetic steel and designing variables to be solved and formulas;

wherein the performance parameter of the magnetic steel includes a magnetic remanence Br of magnetic steel, a remanence tolerance DiffBr, a temperature coefficient of remanence α, an intrinsic coercivity Hcj of magnetic steel, an intrinsic coercivity tolerance DiffHcj, a temperature coefficient of intrinsic coercivity β, a recoil permeability Pm of magnetic steel and an inflection point gap parameter Xc;

the remanence Br and intrinsic coercivity Hcj of magnetic steel is measured at 20° C.;

the variables designed to be solved include a coordinate (Hn, Bn) of the operation point under 20° C. on a BH curve, a loadline slope Pc, an ultimate temperature rise Tm and an ultimate demagnetization temperature Tlim;

the formulas include:

$$Pc = \frac{Bn}{Hn} ;$$

$$Tm = \frac{Br - ( Pc - Pm ) * ( Hcj + Xc )}{( Pc - Pm ) * Hcj * β - Br * α} ;$$

$$T lim = Tm + 20 ;$$

S3. Establishing a finite element model for a magnetic loop system according to the performance parameter of magnetic steel, variables and formulas in S2;

S4. Calculating a value of the coordinate (Hn, Bn) of the operation point under 20° C. on the BH curve, the loadline slope Pc, and the ultimate demagnetization temperature T lim through solving and conducting a steady-state analysis of the finite element model; and

S5. Obtaining a demagnetization curve view with post-treatment.

Ordinary magnetic loop system simulation only focuses on B value among magnetic gaps, so only the remanence parameter Br of magnetic steel is needed to be imported. But now solving the ultimate demagnetization temperature needs an overall FEA simulation for the loudspeaker magnetic loop system, wherein more performance parameters of magnetic steel are imported for a quick solution to obtain a coordinate (Hn, Bn) of operation point N at room temperature (20° C.) on the BH curve and a loadline slope Pc, thus obtaining an ultimate demagnetization temperature T lim after further solution.

Furthermore, since an intrinsic coercivity Hcj, an intrinsic coercivity tolerance DiffHcj, and an inflection point gap parameter Xc are introduced in the present invention, a demagnetization temperature region can be confirmed after adjustment.

As a further description of the technical scheme of the present invention, the remanence of magnetic steel under the ultimate demagnetization temperature T lim is Br(Tlim)=Br+Br*α*Tm; the intrinsic coercivity of magnetic steel under the ultimate demagnetization temperature T lim is Hcj Tlim)=Hcj+Hcj*P*Tm. Wherein, for NdFeB magnets after high temperature demagnetization, both the temperature coefficient α of the remanence and temperature coefficient β of intrinsic coercivity are negative values. Additionally, for ferrite magnets after low temperature demagnetization, the temperature coefficient α of the remanence thereof is a negative value and the temperature coefficient β of intrinsic coercivity is a positive value.

As a further description of the technical scheme of the present invention, the value of an inflection point gap parameter Xc is in a range from 300 to 1500. The value range of the inflection point gap parameter Xc is obtained with a preferential selection by the researchers in experiments. The researchers found that if Xc is not introduced, the Tm obtained by calculation is larger than actual value, i.e. introduction of inflection point gap parameter Xc during calculation and measurement can calculate to obtain the ultimate temperature rise Tm with more accuracy.

As a further description of the technical scheme of the present invention, the magnetic loop system includes one of a 2D axisymmetric magnetic loop system, a non-2D axisymmetric magnetic loop system and a multi-magnetic-steel magnetic loop system. The calculating method for ultimate demagnetization temperature of loudspeaker magnetic steel provided by the present invention can be suitable for calculating the ultimate demagnetization temperature of loudspeaker magnetic steel in any shape and structure, including 2D axisymmetric magnetic loop systems, a non-2D axisymmetric magnetic loop system and a multi-magnetic-steel magnetic loop system, thereby solving the problem that traditional calculating methods for ultimate demagnetization temperature of loudspeaker magnetic steel cannot be suitable for the opposite magnetic loop system and magnetic loop system of multiple magnetic steels.

As a further description of the technical scheme of the present invention, the magnetic steel includes an NdFeB magnet and a ferrite magnet. The calculating method for ultimate demagnetization temperature of loudspeaker magnetic steel provided by the present invention can be suitable for calculating the ultimate demagnetization temperature of loudspeaker magnetic steel in various types of demagnetization, which includes the temperature demagnetization of NEO and the temperature demagnetization of ferrite magnet. And this calculating method doesn't need to introduce the magnetic flux leakage coefficient σ and magnetoresistive coefficient f and also to draw multiple demagnetization curves at different temperatures. This calculating method is quick in calculation, rapid and has a high effectiveness.

As a further description of the technical scheme of the present invention, the establishment, solution, steady-state analysis and post-treatment of the finite element analysis model is conducted in COMSOL multiphysics software such that highly-precise value simulation is ensured and then the demagnetization curve is presented directly after post-treatment.

Based on above technical schemes, the beneficial effects provided by the present invention are as below:

(1) The calculating method for ultimate demagnetization temperature of loudspeaker magnetic steel provided by the present invention is based on FEA simulation of magnetic loop system. Through such method, the coordinate of an operation point at room temperature (20° C.) can be quickly found on BH curve and a value of loadline slope Pc can be further precisely obtained, and the ultimate demagnetization temperature of loudspeaker magnetic steel in loudspeaker magnetic circuit system can be obtained accurately in the end by importing the to-be-solved variables and formulas into FEA simulation through the temperature coefficient of magnetic steel itself. After post-treatment in the end, a demagnetization curve for magnetic steel is presented directly. This can provide overall information of demagnetization temperature for researches and users to enable to estimate effectively the overall performance of loudspeaker.

(2) The calculating method for ultimate demagnetization temperature of loudspeaker magnetic steel provided by the present invention can be suitable for calculating the ultimate demagnetization temperature of loudspeaker magnetic steel in any shape and structure and for calculating the ultimate demagnetization temperature of magnetic steels with various demagnetization types, and is capable of quick solution to precisely obtain the ultimate demagnetization temperature of magnetic steels. It has a wide range of application and an accurate and precise process of calculation.

### BRIEF DESCRIPTION OF THE DRAWINGS

FIG. 1 is a flow chart for embodying the calculating method for ultimate demagnetization temperature of loudspeaker magnetic steel of the present invention;

FIG. 2 is a high temperature demagnetization curve view of the present invention; and

FIG. 3 is a demagnetization curve view of the present invention after post-treatment.

### DETAILED DESCRIPTION

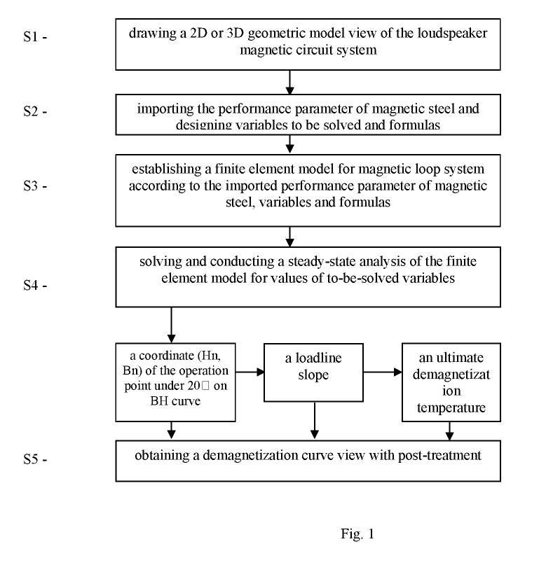

To facilitate understanding, the invention will be described in detail in combination with FIGS. 1-3 and the specific embodiments. The drawings illustrate preferred embodiments of the present invention. However, the present invention can be embodied in many different forms, and is not limited to the embodiments described herein. Rather, the purpose of providing these embodiments is to make the disclosure of the present invention more comprehensively understood.

Unless otherwise defined, all technical and scientific terms used herein have the same meaning as commonly understood by those skilled in the art to which this invention pertains. The terminology used herein in the specification of the present invention is for the purpose of describing particular embodiments only and is not intended to limit the invention.

### Embodiment 1

FIG. 1 illustrates a flow chart for embodying the calculating method for ultimate demagnetization temperature of loudspeaker magnetic steel of the present invention. As shown in the implementation flow chart, a calculating method for ultimate demagnetization temperature of loudspeaker magnetic steel based on FEA simulation of magnetic loop system specifically comprises the following steps:

S1. Drawing a 2D or 3D geometric model view of the loudspeaker magnetic circuit system;

S2. Importing the performance parameter of magnetic steel and designing variables (e.g., Pc, Tm, T lim, etc.) to be solved and formulas;

S3. Establishing a finite element model for magnetic loop system according to the performance parameter of magnetic steel, variables and formulas in S2;

S4. Calculating for a value of the coordinate (Hn, Bn) of the operation point under 20° C. on a BH curve, the loadline slope Pc, and the ultimate demagnetization temperature T lim through solving and conducting a steady-state analysis of the finite element model;

S5. Obtaining a demagnetization curve view with post-treatment.

The performance parameter of the magnetic steel includes a magnetic remanence Br of magnetic steel, a remanence tolerance Difffir, a temperature coefficient of remanence α, an intrinsic coercivity Hcj of magnetic steel, an intrinsic coercivity tolerance DiffHcj, a temperature coefficient of intrinsic coercivity β, a recoil permeability Pm of magnetic steel and an inflection point gap parameter Xc.

In the present embodiment, the room temperature is considered to be 20° C. The above remanence Br and intrinsic coercivity Hcj of magnetic steel is measured at 20° C.

The above variables designed to be solved include a coordinate (Hn, Bn) of the operation point N under room temperature on BH curve, a loadline slope Pc, an ultimate temperature rise Tm and an ultimate demagnetization temperature T lim.

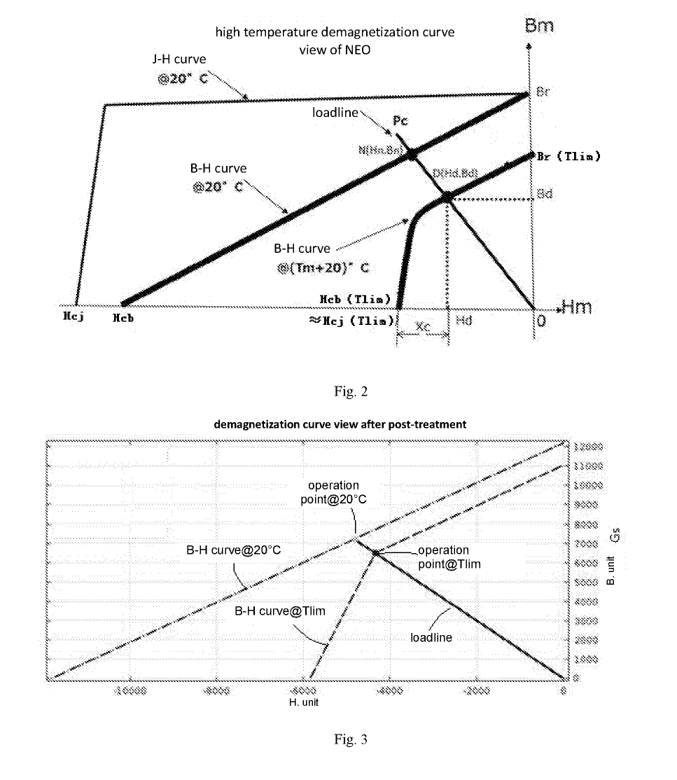

In the calculating method for ultimate demagnetization temperature of loudspeaker magnetic steel of the present invention, solving the variables is key to the present invention. In order to better understand the performance parameter of magnetic steel and the to-be-solved variables, FIG. 2 illustrates a high temperature demagnetization curve view for NEO of the present invention. With reference to FIG. 2, on the high temperature demagnetization curve, vertical coordinate Bm represents the magnetic flux density inside the magnetic steel, which is a positive value; horizontal coordinate Hm represents the magnetic field intensity inside the magnetic steel, which is a negative value; B-H curve@20° C. represents the B-H curve under 20° C. (room temperature), the intersection point of B-H curve@20° C. and the vertical coordinate is remanence Br of the magnetic steel under 20° C. and the intersection point B-H curve@20° C. and the horizontal coordinate is coercivity Hcb of the magnetic steel under 20° C. J-H curve@20° C. represents J-H curve under 20, and the intersection point of J-H curve@20° C. and the horizontal coordinate is intrinsic coercivity Hcj of the magnetic steel under 20VC.

B-H curve@ (Tm+20) ° C. represents B-H curve under ultimate demagnetization temperature; the intersection point of B-H curve@ (Tm+20) ° C. and the vertical coordinate is remanence Br T lim of the magnetic steel under ultimate demagnetization temperature and the intersection point of B-H curve@ (Tm+20) ° C. and the horizontal coordinate is coercivity Hcj (T lim) of the magnetic steel under ultimate demagnetization temperature, here coercivity Hcb(T lim) is about equal to intrinsic coercivity Hcj(Tlim).

When in 20 of room temperature, the difference between intrinsic coercivity Hcj and coercivity Hcb is larger and Hcb>Hcj; with the rise of temperature, both Hcj and Hcb becomes larger gradually, but Hcj changes so fast that it gradually closes to Hcb.

Since coercivity Hcb(T lim) is about equal to intrinsic coercivity Hcj(Tlim) on B-H curve@ (Tm+20) ° C., an inflection point occurs on B-H curve@ (Tm+20) ° C.

Pc is loadline slope, which may not change with the temperature; the intersection of loadline and B-H curve@20° C. is the operation point N of magnetic steel with a coordinate of (Hn, Bn).

B-H curves of magnetic steel under different temperatures are different, i.e. the operation points are different, but the slope of loadline remains consistent.

Pm is recoil permeability of magnetic steel, which also doesn't change with the temperature.

Xc is inflection point gap parameter. With a further reference to FIG. 2, Xc also represents the difference on X axis between the inflection point and Hcb(Tlim) on B-H curve under ultimate demagnetization temperature T lim, the value being ranged from 300 to 1500 Oe. The value range of inflection point gap parameter Xc is obtained with a preferential selection by the researchers in experiments. Through researches and comparison, the researchers found that if Xc is not introduced, the Tm obtained by calculation is larger than actual value, i.e. introduction of inflection point gap parameter Xc during calculation and measurement can calculate to obtain the ultimate temperature rise Tm with more accuracy.

Furthermore, since an intrinsic coercivity Hcj, an intrinsic coercivity tolerance DiffHcj, and an inflection point gap parameter Xc are introduced in the present embodiment, a demagnetization temperature region can be confirmed after adjustment of the value of Xc based on the validation test result.

In addition, for NdFeB magnets after high temperature demagnetization, both the temperature coefficient α of the remanence and temperature coefficient β of intrinsic coercivity are negative values. Additionally, for ferrite magnets after low temperature demagnetization, the temperature coefficient α of the remanence thereof is a negative value, temperature coefficient β of intrinsic coercivity is a positive value.

Based on remanence Br, intrinsic coercivity Hcj, temperature coefficient of remanence α, temperature coefficient of intrinsic coercivity β and ultimate temperature rise, it can be acquired that:

the remanence of magnetic steel under the ultimate demagnetization temperature T lim is Br(T lim)=Br+Br*α*Tm;

the intrinsic coercivity of magnetic steel under the ultimate demagnetization temperature Tlim is Hcj (Tlim)=Hcj+Hcj*β*Tm.

The intersection of loadline and B-H curve@(Tm+20) ° C. is the operation point D of magnetic steel under such temperature with a coordinate of (Hd, Bd).

Further, based on above performance parameter of magnetic steel and to-be-solved variables, it can be deduced with relative formulas according to the principle of demagnetization that:

$$Pc = \frac{Bd}{Hd} = \frac{Bn}{Hn} ;$$

$$Tm = \frac{Br - ( Pc - Pm ) * ( Hcj + Xc )}{( Pc - Pm ) * Hcj * β - Br * α} ;$$

$$T lim = Tm + 20 ;$$

Ordinary magnetic loop system simulation only focuses on the B value among magnetic gaps, so only the remanence parameter Br of magnetic steel is needed to be imported. But now solving the ultimate demagnetization temperature needs an overall FEA simulation for the loudspeaker magnetic loop system, wherein more performance parameters of magnetic steel are imported to conduct variable-solution and steady-state analysis for a quick solution to obtain a coordinate (Hn, Bn) of operation point N at room temperature (20° C.) on BH curve and a loadline slope Pc, thus obtaining an ultimate demagnetization temperature Tlim after further solution.

In the present embodiment, values for the imported performance parameter of magnetic steel are shown in Table 1 as below:

TABLE 1
Imparted performance parameter of magnetic
steel (20° C.) and specific values

| Name for performance | | |
|---|---|---|
| parameter of magnetic | | |
| steel | Value | Description |
| Br | 12200 | Remanence of magnetic steel, Gs |
| DiffBr | 200 | Remanence tolerance, Gs |
| Hcj | −14000 | Intrinsic coercivity of magnetic |
| | | steel, Oe |
| DiffHcj | 300 | Intrinsic coercivity tolerance, Oe |
| β | −0.0063 | Temperature coefficient of intrinsic |
| | | coercivity |
| α | −0.0012 | Temperature coefficient of |
| | | remanence |
| Xc | 800 | Inflection point gap parameter. |
| Pm | 1.05 | Recoil permeability of magnetic |
| | | steel |

Above performance parameters of magnetic steel and variables designed to be solved are imported into COMSOL Multiphysics software and a finite element model for magnetic loop system is established; then a solution and a steady-state analysis on the finite element model are conducted for values of variables that are to be solved, then a coordinate (Hn, Bn), a loadline slope Pc value and an ultimate demagnetization temperature value of the operation point under 20° C. on BH curve are obtained after calculation. Then after a series of post-treatments (i.e., data handling for the simulated result and combining the initial data to output figures for improved understanding for technicians):

(1) Coordinate (Hn, Bn) of operation point N at 20° C. room temperature is imported, the line connecting the coordinate origin of demagnetization curve with the operation point N being the loadline;

(2) BH curve at 20° C. room temperature is imported, i.e., the line connecting (0, Br) with (Hcj, 0) is imported;

(3) BH curve at ultimate demagnetization temperature Tlim is imported, i.e. The line connecting (0, Br(T lim)), (Hd, Bd) and (Hcj (T lim), 0).

Among which:

the remanence of magnetic steel under the ultimate demagnetization temperature T lim is Br(Tlim)=Br+Br*α*Tm;

the intrinsic coercivity of magnetic steel under the ultimate demagnetization temperature T lim is Hcj (T lim)=Hcj+Hcj*β*Tm.

the horizontal coordinate of operation point at ultimate demagnetization temperature T lim: Hd=Hcj+Hcj*β*Tm+Xc;

the vertical coordinate of operation point at ultimate demagnetization temperature T lim:

Bd=(Br+Br*α*Tm)+(Hcj+Hcj*β*Tm+Xc)*Pm;

After above post-treatments, a treated demagnetization curve shown in FIG. 3 is presented directly. This can provide overall information of demagnetization temperature for researches and users to enable to estimate effectively the overall performance of loudspeaker.

The calculating method for ultimate demagnetization temperature of loudspeaker magnetic steel provided by the present invention can be suitable for calculating the ultimate demagnetization temperature of loudspeaker magnetic steel in any shape and structure, including 2D axisymmetric magnetic loop system, a non-2D axisymmetric magnetic loop system and a multi-magnetic-steel magnetic loop system, thereby solving the problem that traditional calculating method for ultimate demagnetization temperature of loudspeaker magnetic steel cannot be suitable for the opposite magnetic loop system and magnetic loop system of multiple magnetic steels.

The calculating method for ultimate demagnetization temperature of loudspeaker magnetic steel provided by the present embodiment can be suitable for calculating the ultimate demagnetization temperature of loudspeaker magnetic steel in various types of demagnetization, which includes the temperature demagnetization of NEO (NdFeB magnet) and the temperature demagnetization of ferrite magnet. This calculation method does not need to introduce the magnetic flux leakage coefficient σ and magnetoresistive coefficient f and also to draw multiple demagnetization curves at different temperatures. This calculating method is quick in calculation, rapid and has a high effectiveness.

The foregoing is merely illustrative and illustrative of the structure of the invention, and the description thereof is more specific and detailed, but is not to be construed as limiting the scope of the invention. It should be noted that various modifications and improvements can be made by those skilled in the art without departing from the spirit of the invention, and these obvious alternatives are within the scope of the present invention.

1. A calculating method for ultimate demagnetization temperature of loudspeaker magnetic steel, comprising:
drawing a 2D or 3D geometric model view of the loudspeaker magnetic circuit system;
importing performance parameters of magnetic steel and designing variables to be solved and formulas, the performance parameters of the magnetic steel including a magnetic remanence Br of magnetic steel, a remanence tolerance DiffBr, a temperature coefficient of remanence α, an intrinsic coercivity Hcj of magnetic steel, an intrinsic coercivity tolerance DiffHcj, a temperature coefficient of intrinsic coercivity β, a recoil permeability Pm of magnetic steel and an inflection point gap parameter Xc, wherein the remanence Br and intrinsic coercivity Hcj of magnetic steel is measured at 20° C., variables designed to be solved including a coordinate (Hn, Bn) of an operation point under 20° C. on a BH curve, a loadline slope Pc, an ultimate temperature rise Tm and an ultimate demagnetization temperature T lim, the formulas including:
$$Pc = \frac{Bn}{Hn} ;$$
$$Tm = \frac{Br - ( Pc - Pm ) * ( Hcj + Xc )}{( Pc - Pm ) * Hcj * β - Br * α} ;$$
$$T lim = Tm + 20 ;$$
establishing a finite element model for a magnetic loop system according to the performance parameters of magnetic steel, the variables and the formulas;
calculating a value of the coordinate (Hn, Bn) of the operation point under 20° C. on the BH curve, the loadline slope Pc, and the ultimate demagnetization temperature T lim through solving and conducting a steady-state analysis of the finite element model; and
obtaining a demagnetization curve view with post-treatment.

2. The calculating method for ultimate demagnetization temperature of loudspeaker magnetic steel according to claim 1, wherein a remanence of magnetic steel under the ultimate demagnetization temperature T_lim is Br(T_lim)=Br+Br*α*Tm; and an intrinsic coercivity of magnetic steel under the ultimate demagnetization temperature T_lim is Hcj (T_lim)=Hcj+Hcj*β*Tm.

3. The calculating method for ultimate demagnetization temperature of loudspeaker magnetic steel according to claim 1, wherein the value of ante inflection point gap parameter Xc is ranged in a range from 300 to 1500.

4. The calculating method for ultimate demagnetization temperature of loudspeaker magnetic steel according to claim 1, wherein the magnetic loop system includes one of a 2D axisymmetric magnetic loop system, a non-2D axisymmetric magnetic loop system and a multi-magnetic-steel magnetic loop system.

5. The calculating method for ultimate demagnetization temperature of loudspeaker magnetic steel according to claim 1, wherein the magnetic steel includes one of an NdFeB magnet and a ferrite magnet.

6. The calculating method for ultimate demagnetization temperature of loudspeaker magnetic steel according to claim 1, wherein an establishment, a solution, steady-state analysis and post-treatment of the finite element analysis model are conducted in a Multiphysics software.
